(19) United States
(12) Patent Application Publication
(10) Pub. No.: US 2026/0059918 A1
(43) Pub. Date: Feb. 26, 2026

(54) LIGHT-EMITTING MODULE AND METHOD FOR MANUFACTURING THE SAME

(71) Applicant: NICHIA CORPORATION, Anan-shi (JP)

(72) Inventors: Kosuke SATO, Anan-shi (JP); Daisuke SANGA, Tokushima-shi (JP)

(73) Assignee: NICHIA CORPORATION, Anan-shi (JP)

(21) Appl. No.: 19/291,173

(22) Filed: Aug. 5, 2025

(30) Foreign Application Priority Data
Aug. 21, 2024 (JP) 2024-139970

(51) Int. Cl. H10H 29/49; H10H 29/01; H10H 29/80

(52) U.S. Cl. CPC H10H 29/49; H10H 29/012; H10H 29/8321

(57) ABSTRACT

A method for manufacturing a light-emitting module includes: providing a light-emitting element including a semiconductor layered body, a first electrode part, second electrode parts, and an insulating part disposed in areas between the first electrode part and the second electrode parts and at least one of areas between adjacent second electrode parts on the first surface, the insulating part protruding further away from the first surface than the first electrode part and the second electrode parts; providing an intermediate structure including a wiring substrate, a first conductive part, second conductive parts, and a holding part disposed in areas between the first conductive part and the second conductive parts and at least one of areas between adjacent second conductive parts on the second surface; disposing the light-emitting element on the intermediate structure; and forming the first bonding part and the second bonding part.

### CROSS REFERENCE TO RELATED APPLICATION

This application claims priority to Japanese Patent Applications No. 2024-139970, filed on Aug. 21, 2024, the entire contents of which are hereby incorporated by reference.

### BACKGROUND

### Technical Field

The present disclosure relates to a light-emitting module and a method for manufacturing the same.

### Background Art

A light-emitting module including a large number of light-emitting elements mounted on a wiring substrate has been developed. When such a light-emitting module is manufactured, the large number of light-emitting elements are disposed on one wiring substrate, and then the wiring substrate and the light-emitting elements are bonded to each other. However, a bonding strength between the wiring substrate and the light-emitting element may decrease if a position of the light-emitting element is shifted with respect to the wiring substrate (for example, see PCT Publication No. WO2015/033557).

### SUMMARY

It is an object of certain embodiments of the present disclosure to provide a light-emitting module in which a bonding strength between a wiring substrate and a light-emitting element is less likely to decrease even if a position of the light-emitting element is shifted with respect to the wiring substrate, and a method for manufacturing the light-emitting module.

A method for manufacturing a light-emitting module according to an aspect of the present invention includes: providing a light-emitting element including a semiconductor layered body including a first surface, a first electrode part disposed on the first surface, a plurality of second electrode parts disposed on the first surface to be separated from the first electrode part, and an insulating part disposed in areas between the first electrode part and the plurality of second electrode parts and at least one of areas between adjacent ones of the plurality of second electrode parts on the first surface, the insulating part protruding further away from the first surface than the first electrode part and the plurality of second electrode parts protrude; providing an intermediate structure including a wiring substrate including a second surface, a first conductive part disposed on the second surface, a plurality of second conductive parts disposed on the second surface to be separated from the first conductive part, and a holding part disposed in areas between the first conductive part and the plurality of second conductive parts and at least one of areas between adjacent ones of the plurality of second conductive parts on the second surface; disposing the light-emitting element on the intermediate structure by bringing the insulating part into contact with the holding part; and forming a first bonding part and a second bonding part, the first bonding part being in contact with the first electrode part and the first conductive part, and the second bonding part being in contact with the second electrode part and the second conductive part.

A light-emitting module according to an aspect of the present invention includes a light-emitting element including a semiconductor layered body including a first surface, a first electrode part disposed on the first surface, a plurality of second electrode parts disposed on the first surface to be separated from the first electrode part, and an insulating part disposed in areas between the first electrode part and the plurality of second electrode parts and at least one of areas between adjacent ones of the plurality of second electrode parts on the first surface, the insulating part protruding further away from the first surface than the first electrode part and the plurality of second electrode parts protrude; a wiring substrate including a second surface; a first conductive part disposed on the second surface; a plurality of second conductive parts disposed on the second surface to be separated from the first conductive part; a first bonding part in contact with the first conductive part and an entirety of a surface of the first electrode part facing the second surface; and a second bonding part in contact with the second conductive part and an entirety of a surface of the second electrode part facing the second surface.

According to certain embodiments of the present disclosure, there can be provided a light-emitting module in which a bonding strength between a wiring substrate and a light-emitting element is less likely to decrease even when a position of the light-emitting element is shifted with respect to the wiring substrate, and the method for manufacturing the light-emitting module.

### BRIEF DESCRIPTION OF THE DRAWINGS

FIG. 1 is a schematic bottom view illustrating a light-emitting element in an embodiment.

FIG. 2 is a schematic end view taken along line II-II illustrated in FIG. 1.

FIG. 3 is a schematic top view illustrating an intermediate structure in the embodiment.

FIG. 4 is a schematic top view illustrating a portion of an intermediate structure in the embodiment excluding a holding part.

FIG. 5 is a schematic end view taken along line V-V illustrated in FIG. 3.

FIG. 6 is a schematic top view illustrating a state in which a plurality of light-emitting elements are disposed on the intermediate structure.

FIG. 7 is a schematic end view taken along line VII-VII illustrated in FIG. 6.

FIG. 8 is a schematic top view illustrating a step of forming a first bonding part and a second bonding part.

FIG. 9 is a schematic end view taken along line IX-IX illustrated in FIG. 8.

FIG. 10 is a schematic top view illustrating a step of forming the first bonding part and the second bonding part.

FIG. 11 is a schematic end view taken along line XI-XI illustrated in FIG. 10A.

FIG. 12 is a schematic top view illustrating a step of removing a holding part.

FIG. 13 is a schematic end view taken along line XIII-XIII illustrated in FIG. 12.

FIG. 14 is a schematic top view illustrating a step of forming a light shielding part.

FIG. 15 is a schematic end view taken along line XV-XV illustrated in FIG. 14.

FIG. 16 is a schematic end view illustrating effects of the embodiment.

FIG. 17 is a schematic end view illustrating a method for manufacturing a light-emitting module according to a comparative example, and illustrates a case in which a positional shift of a light-emitting element with respect to a wiring substrate is small.

FIG. 18 is a schematic end view illustrating the method for manufacturing the light-emitting module according to the comparative example, and illustrates a case in which a positional shift of the light-emitting element with respect to the wiring substrate is large.

### DETAILED DESCRIPTION

Embodiments of the present invention are described below with reference to the drawings. All the drawings are illustrated schematically and may be exaggerated or simplified as appropriate. The dimensional ratios of components are not necessarily consistent throughout the drawings.

First, a method for manufacturing a light-emitting module according to the present embodiment will be described.

The method for manufacturing a light-emitting module according to the present embodiment includes a step of providing light-emitting elements 10, a step of providing an intermediate structure 30, a step of disposing the light-emitting elements 10 on the intermediate structure 30, and a step of forming a first bonding part 41 and a second bonding part 42. The light-emitting element 10 includes a semiconductor layered body 20 including a first surface 26, a first electrode part 11 disposed on the first surface 26, a plurality of second electrode parts 12 disposed on the first surface 26 to be separated from the first electrode part 11, and insulating parts 13. The insulating part 13 is disposed in areas between the first electrode part 11 and the plurality of second electrode parts 12 and at least one of areas between adjacent ones of the plurality of second electrode parts 12 on the first surface 26, and protrudes further away from the first surface 26 than the first electrode part 11 and the plurality of second electrode parts 12 protrude.

The intermediate structure 30 includes a wiring substrate 35 including a second surface 36, a first conductive part 31 disposed on the second surface 36, a plurality of second conductive parts 32 disposed on the second surface 36 to be separated from the first conductive part 31, and a holding part 33. The holding part 33 is disposed in areas between the first conductive part 31 and the plurality of second conductive parts 32 and at least one of areas between adjacent ones of the plurality of second conductive parts 32 on the second surface 36. In the step of disposing the light-emitting elements 10 on the intermediate structure 30, the insulating part 13 is brought into contact with the holding part 33. The first bonding part 41 is in contact with the first electrode part 11 and the first conductive part 31. The second bonding part 42 is in contact with the second electrode part 12 and the second conductive part 32.

Details of each step will be described below.

### Step of Providing Light-Emitting Elements

First, the light-emitting elements 10 are provided.

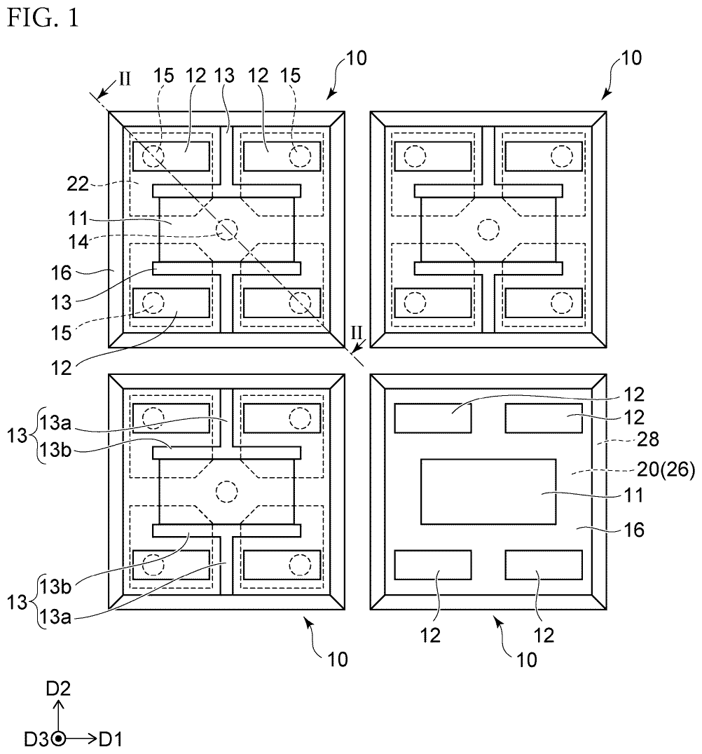

FIG. 1 is a schematic bottom view illustrating the light-emitting elements in the present embodiment.

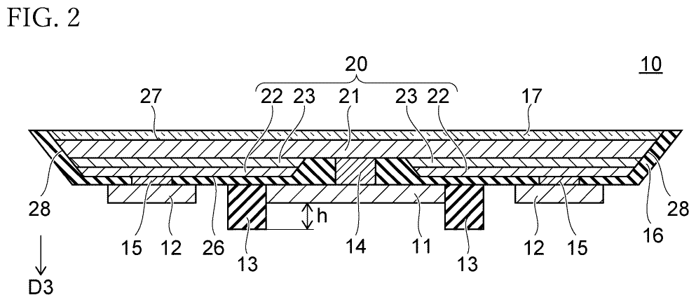

FIG. 2 is a schematic end view taken along line II-II illustrated in FIG. 1.

Although four light-emitting elements 10 are illustrated in FIG. 1, to make other components easier to see, the insulating part 13, a first contact 14, a second contact 15, and a second semiconductor layer 22 are omitted in the light-emitting element 10 at the lower right in the drawing.

As illustrated in FIGS. 1 and 2, the light-emitting element 10 includes the semiconductor layered body 20, the first electrode part 11, the plurality of second electrode parts 12, and the insulating parts 13. The light-emitting element 10 may further include the first contact 14, a plurality of the second contacts 15, an insulating film 16, and a light-transmissive member 17.

The semiconductor layered body 20 includes a first semiconductor layer 21 of a first conductivity type, a plurality of active layer parts 23, and a plurality of the second semiconductor layer parts 22 of a second conductivity type. For example, the first conductivity type is n-type, and the second conductivity type is p-type. However, the first conductivity type may be the p-type, and the second conductivity type may be the n-type. The first semiconductor layer 21, a first of the plurality of active layer parts 23, and a first respective one of the plurality of second semiconductor layer parts 22 are layered in this order. Additionally, the first semiconductor layer 21, a second one of the plurality of active layer parts 23, and a second respective one of the plurality of second semiconductor layer parts 22 are layered in this order.

In the present embodiment, four active layer parts 23 are in contact with one first semiconductor layer 21, and each of the four second semiconductor layer parts 22 is in contact with a corresponding one of the four active layers 23. The semiconductor layered body 20 of the present embodiment includes four partial layered bodies, in each of which one active layer part 23 and one second semiconductor layer part 22 are layered, and the four partial layered bodies are arrayed in a matrix of two rows and two columns along a first direction D1 and a second direction D1 orthogonal to the first direction D2.

The semiconductor layered body 20 includes the first surface 26 that is a lower surface, an upper surface 27 located on a side opposite to the first surface 26, and a plurality of lateral surfaces 28 each connecting the first surface 26 and the upper surface 27. The shape of the semiconductor layered body 20 is, for example, a frustum of a square pyramid. In this case, the shapes of the first surface 26 and the upper surface 27 are rectangular, and the upper surface 27 is larger than the first surface 26 that is the lower surface. Further, four lateral surfaces 28 are provided.

The first electrode part 11 is disposed on the first surface 26 of the semiconductor layered body 20. The plurality of second electrode parts 12 are disposed on the first surface 26 to be separated from the first electrode part 11. The plurality of second electrode parts 12 are also separated from each other. In the present embodiment, the first electrode part 11 is disposed, for example, at the center of the first surface 26. The shape of the first electrode part 11 is, for example, rectangular, and the length in the first direction D1 is greater than the length in the second direction D2.

The light-emitting element 10 of the present embodiment includes four second electrode parts 12 arrayed in a matrix of two rows and two columns along the first direction D1 and the second direction D2. Each second electrode part 12 is disposed at a position corresponding to a respective second semiconductor layer part 22 of the semiconductor layered body 20, for example, at a respective corner portion of the first surface 26. The shape of each second electrode part 12 is, for example, rectangular, and the length in the first direction D1 is greater than the length in the second direction D2. The shapes of the second electrode parts 12 are substantially the same shape as each other and each of them is smaller than the shape of the first electrode part 11. The first electrode part 11 is not disposed between the two second electrode parts 12 arrayed along the first direction D1, but is disposed in a portion of an area between the two second electrode parts 12 arrayed along the second direction D2.

The first electrode part 11 is connected to the first semiconductor layered body 21 via the first contact 14. Note that in this specification, “connected” refers to being electrically connected. The plurality of second electrode parts 12 are connected to the plurality of second semiconductor layer parts 22 via the plurality of second contacts 15. More specifically, each second electrode part 12 is connected to a corresponding second semiconductor layer part 22 via a corresponding second contact 15. When the first semiconductor layer 21 is an n-type semiconductor layer and the second semiconductor layer 22 is a p-type semiconductor layer, the first electrode part 11 is a common cathode electrode and the second electrode parts 12 are anode electrodes.

The insulating film 16 covers the first surface 26 of the semiconductor layered body 20 and the lateral surfaces 28. The first electrode part 11 is separated from the first semiconductor layer 21 with the insulating film 16 interposed therebetween, and the second electrode part 12 is separated from the second semiconductor layer 22 with the insulating film 16 interposed therebetween. The first contact 14 and the second contact 15 penetrate through the insulating film 16. The light-transmissive member 17 covers the upper surface 27 of the semiconductor layered body 20. An upper surface of the light-transmissive member 17 is a light emission surface of the light-emitting element 10. Fine protrusions and recessions may be formed on the upper surface of the light-transmissive member 17. This improves the light extraction efficiency from the light-transmissive member 17.

The insulating part 13 is disposed in areas between the first electrode part 11 and the plurality of second electrode parts 12 and at least one of areas between adjacent ones of the plurality of second electrode parts 12 on the first surface 26 of the semiconductor layered body 20. The insulating part 13 covers neither the first electrode part 11 nor the second electrode parts 12.

In the present embodiment, for example, the insulating part 13 includes a first portion 13a extending in the second direction D2 and a second portion 13b extending in the first direction D1. The first portion 13a is disposed between two second electrode parts 12 arrayed along the first direction D1. The second portion 13b is disposed between the first electrode part 11 and each second electrode part 12 in the second direction D2. A central portion of the second portion 13b in the first direction D1 is connected to an end portion of the first portion 13a on the first electrode part 11 side.

On the other hand, the insulating part 13 is not disposed between the first electrode part 11 and each of end edges of the light-emitting element 10 on two opposite sides in the first direction D1. Further, the insulating part 13 is also not disposed between each second electrode part 12 and the end edge of the light-emitting element 10 on one side in the first direction D1, that is, between the second electrode part 12 and the closest end edge in the first direction D1.

The insulating part 13 protrudes in a third direction D3 further away from the first surface 26 than the first electrode part 11 and the second electrode part 12 do. The third direction D3 is orthogonal to both the first direction D1 and the second direction D2. In the third direction D3, protrusion length h of the insulating part 13 with respect to the first electrode part 11 is preferably in a range of 0.5 μm to 2.0 μm. The insulating part 13 is made of, for example, an insulating material such as silicon oxide (SiO₂) or aluminum oxide (Al₂O₃).

### Step of Providing Intermediate Structure

Subsequently, the intermediate structure 30 is provided.

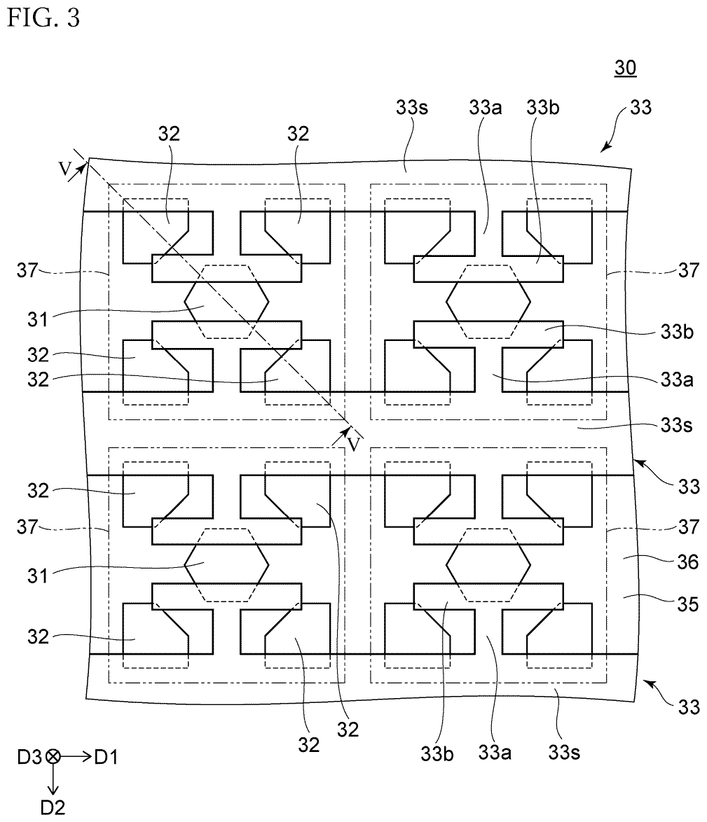

FIG. 3 is a schematic top view illustrating the intermediate structure in the present embodiment.

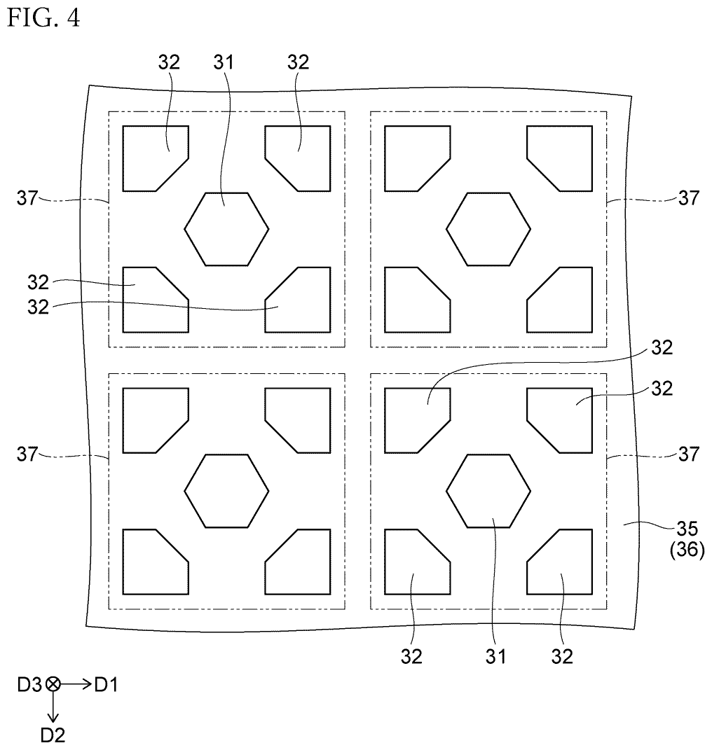

FIG. 4 is a schematic top view illustrating a portion of the intermediate structure in the present embodiment excluding the holding part.

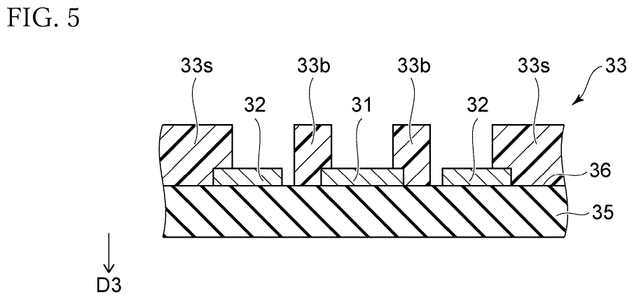

FIG. 5 is a schematic end view taken along line V-V illustrated in FIG. 3.

Note that either the step of providing the light-emitting elements 10 or the step of providing the intermediate structure 30 may be performed first, or they may be performed simultaneously.

As illustrated in FIGS. 3 to 5, the intermediate structure 30 includes the wiring substrate 35, the plurality of first conductive parts 31, the plurality of second conductive parts 32, and the holding part 33. The wiring substrate 35 includes the second surface 36 that is an upper surface. The wiring substrate 35 is, for example, an application specific integrated circuit (ASIC) substrate, and an integrated circuit (not illustrated) is provided inside the wiring substrate 35.

The first conductive part 31 is disposed on the second surface 36 of the wiring substrate 35. The second conductive part 32 is disposed on the second surface 36 to be separated from the first conductive part 31. A plurality of regions 37 in each of which the light-emitting element 10 is to be disposed in a subsequent step are set on the second surface 36. In the present embodiment, the plurality of regions 37 are arrayed in a matrix to be separated from each other along the first direction D1 and the second direction D2, and the shape of each region 37 is rectangular. Note that the first direction D1, the second direction D2, and the third direction D3 of the intermediate structure 30 coincide with the first direction D1, the second direction D2, and the third direction D3, respectively, of the light-emitting element 10 when the light-emitting element 10 is disposed on the intermediate structure 30 in a subsequent step.

In each region 37, one first conductive part 31 is provided, and the plurality of second conductive parts 32 are provided. The positions of the first conductive part 31 and the plurality of second conductive parts 32 in each region 37 correspond to the positions of the first electrode part 11 and the plurality of second electrode parts 12, respectively, in each light-emitting element 10. That is, the first conductive part 31 is disposed at the center of the region 37, and the four second conductive parts 32 are disposed at respective corner portions of the region 37. In one example, the shape of the first conductive part 31 is a regular hexagon, and the shape of each second conductive part 32 is a pentagon formed by cutting off one corner portion of a square facing the first conductive part 31. The first conductive part 31 and the plurality of second conductive parts 32 are connected to wiring lines (not illustrated) of the wiring substrate 35.

The holding part 33 is made of, for example, a resist material and is formed by lithography. The holding part 33 is disposed in areas between the first conductive part 31 and the plurality of second conductive parts 32 and at least one of areas between adjacent ones of the plurality of second conductive parts 32 on the second surface 36 of the wiring substrate 35. In the present embodiment, a portion of the holding part 33 is disposed at a position overlapping the insulating part 13 when viewed from the third direction D3 when the light-emitting elements 10 are disposed on the intermediate structure 30 in a subsequent step. The thickness of the holding part 33, that is, the length in the third direction D3, is greater than the thickness of the first conductive part 31 and the second conductive part 32. Thus, the holding part 33 protrudes further away from the second surface 36 than the first conductive part 31 and the second conductive part 32 protrude.

In the present embodiment, the holding part 33 includes a trunk portion 33s, a first branch portion 33a, and a second branch portion 33b. The trunk portion 33s is located between adjacent ones of the regions 37 in the second direction D2 and extends in the first direction D1. Both end portions, in a width direction, of the trunk portion 33s are located in the region 37 and cover parts of corresponding second conductive parts 32.

The first branch portion 33a extends from the trunk portion 33s toward both sides in the second direction D2. The first branch portion 33a extends from the trunk portion 33s toward the first conductive part 31 in the region 37. The second branch portion 33b extends from a distal end portion of the first branch portion 33a, that is, an end portion of the first branch portion 33a on a side opposite to the trunk portion 33s toward both sides in the first direction D1. The second branch portion 33b is located in the region 37, a central portion of the second branch portion 33b in the first direction D1 covers a portion of the first conductive part 31, and both end portions of the second branch portion 33b in the first direction D1 cover portions of corresponding two second conductive parts 32. The holding part 33 need not cover the first conductive part 31 and the second conductive part 32.

The trunk portion 33s of the holding part 33 is disposed between the adjacent ones of the regions 37 in the second direction D2. End portions of each region 37 on both sides in the second direction D2 are covered with the trunk portion 33s of the holding part 33. In each region 37, the first branch portion 33a of the holding part 33 is disposed between adjacent ones of the second conductive parts 32 in the first direction D1. In each region 37, the second branch portion 33b of the holding part 33 is disposed between the first conductive part 31 and the second conductive part 32.

On the other hand, the holding part 33 is not disposed in a large portion between adjacent ones of the regions 37 in the first direction D1. The holding part 33 is also not disposed between the first conductive part 31 and the end edges of the region 37 on both sides in the first direction D1. The holding part 33 is also not disposed between each second conductive part 32 and the end edge of the region 37 closest to the second conductive part 32 in the first direction D1.

### Step of Disposing Light-Emitting Elements on Intermediate Structure

Subsequently, the light-emitting elements 10 are disposed on the intermediate structure 30.

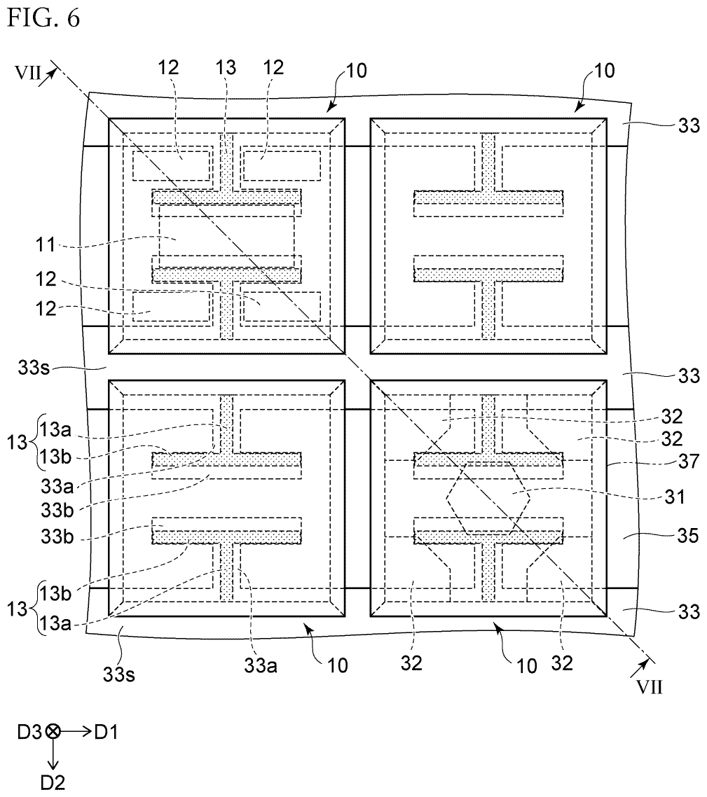

FIG. 6 is a schematic top view illustrating a state in which the plurality of light-emitting elements are disposed on the intermediate structure.

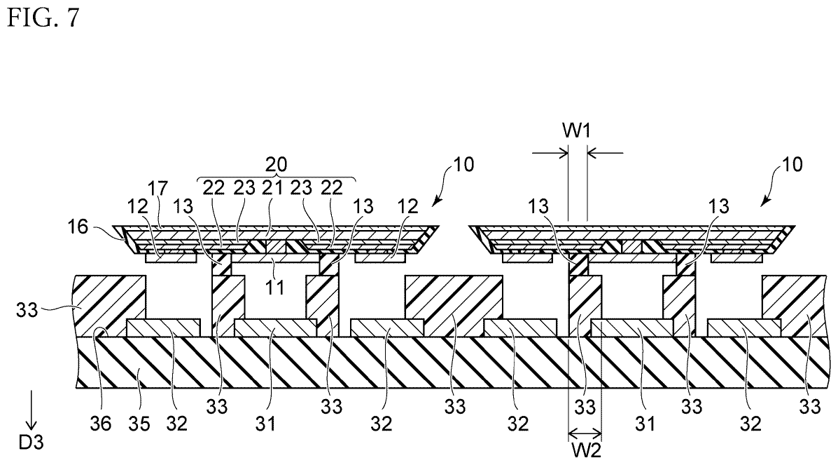

FIG. 7 is a schematic end view taken along line VII-VII illustrated in FIG. 6.

Although four light-emitting elements 10 are illustrated in FIG. 6, in order to make the drawing easier to see, the first electrode part 11 and the second electrode parts 12 are indicated by broken lines in the light-emitting element 10 at the upper left in the drawing, and the first conductive part 31 and the second conductive parts 32 are indicated by broken lines in the region 37 corresponding to the light-emitting element 10 at the lower right in the drawing.

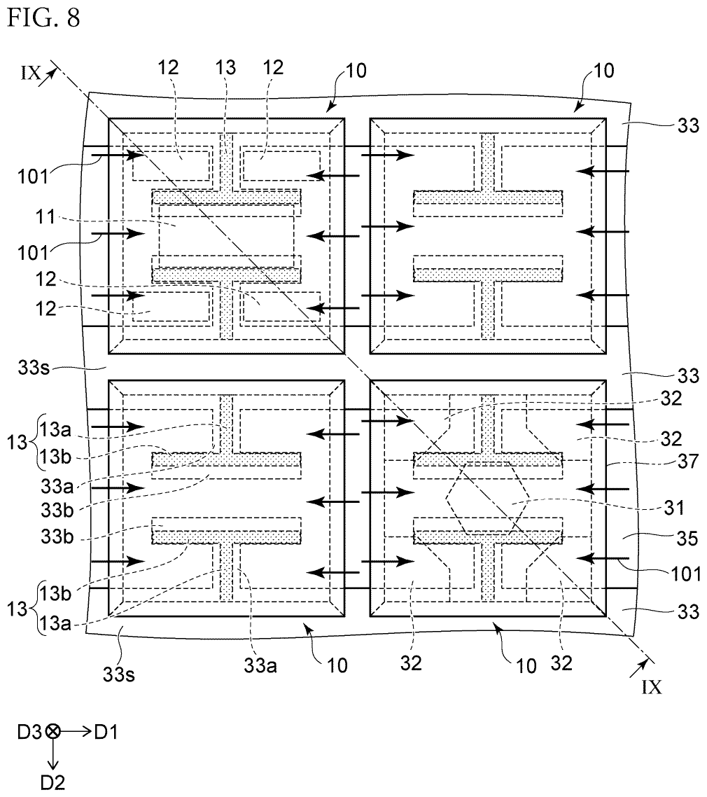

However, the first electrode part 11 and the second electrode parts 12 are provided in all the light-emitting elements 10, and the first conductive part 31 and the second conductive parts 32 are provided in all the regions 37. The same applies to FIGS. 8, 10, and 12 described below. In the description of the steps subsequent to the present step, the third direction D3 is a direction from the first surface 26 toward the second surface 36.

As illustrated in FIGS. 6 and 7, each of the plurality of light-emitting elements 10 is located on a corresponding one of the plurality of regions 37 of the intermediate structure 30 such that the first surface 26 of the light-emitting element 10 faces the second surface 36 of the intermediate structure 30. Then, the insulating part 13 of the light-emitting element 10 is brought into contact with the holding part 33 of the intermediate structure 30. To be more specific, the first portion 13a of the insulating part 13 is brought into contact with the first branch portion 33a of the holding part 33, and the second portion 13b of the insulating part 13 is brought into contact with the second branch portion 33b of the holding part 33. Thus, the plurality of light-emitting elements 10 are disposed on the intermediate structure 30. At this time, as illustrated in FIG. 7, a width W1 of the insulating part 13 is smaller than a width W2 of the holding part 33 in one cross section.

### Step of Forming First Bonding Part and Second Bonding Part

Subsequently, the first bonding part 41 that connects the first electrode part 11 to the first conductive part 31 and the second bonding part 42 that connects the second electrode part 12 to the second conductive part 32 are formed.

FIG. 8 is a schematic top view illustrating a step of forming the first bonding part and the second bonding part.

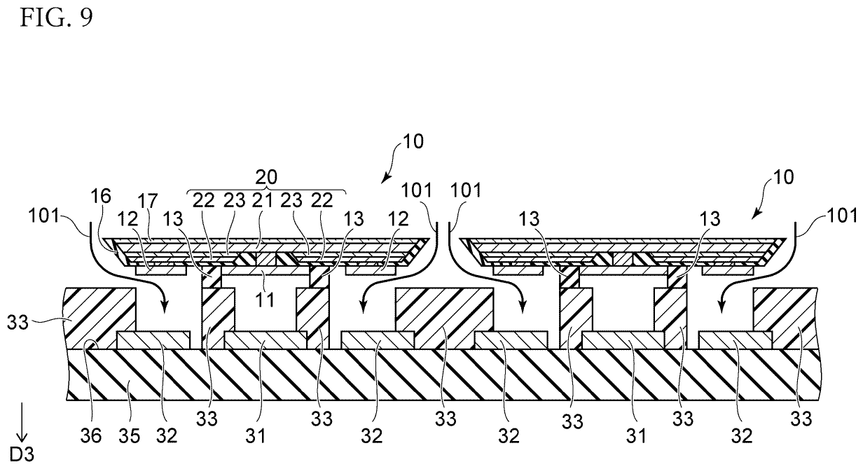

FIG. 9 is a schematic end view taken along line IX-IX illustrated in FIG. 8.

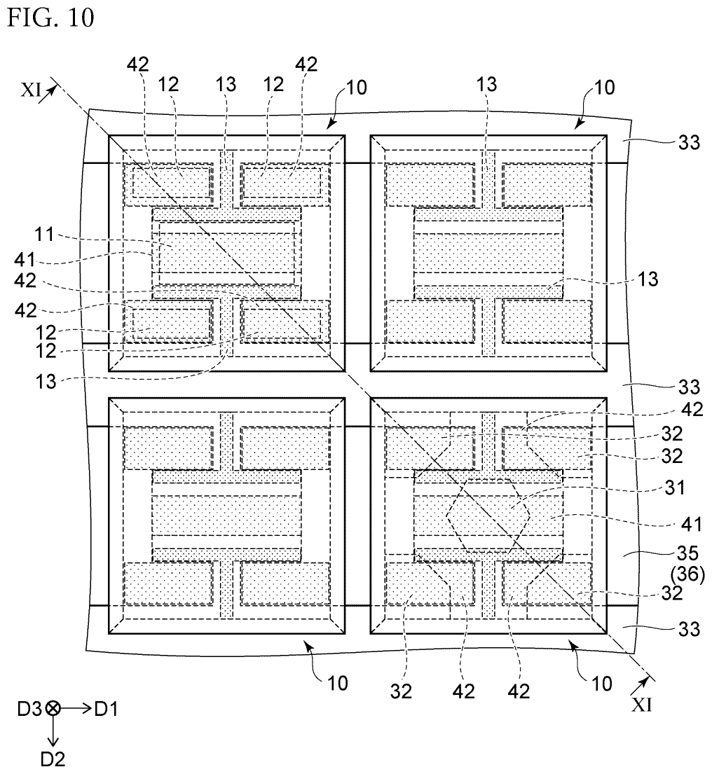

FIG. 10 is a schematic top view illustrating a step of forming the first bonding part and the second bonding part.

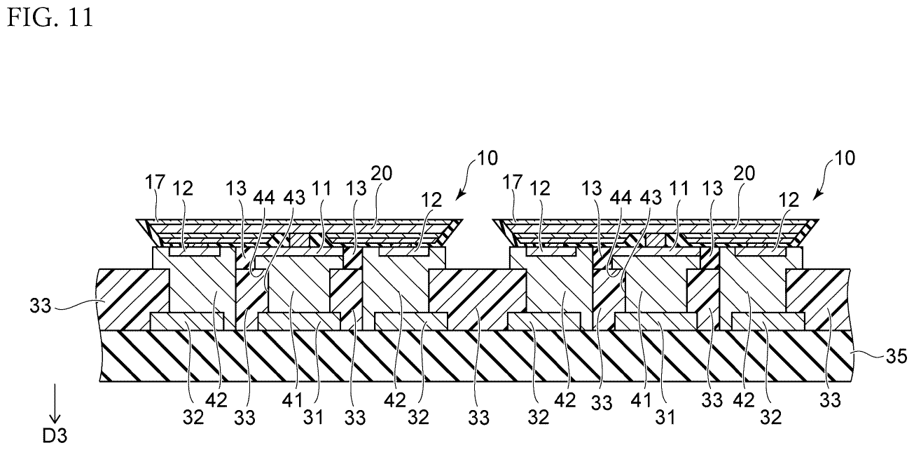

FIG. 11 is a schematic end view taken along line XI-XI illustrated in FIG. 10.

As illustrated in FIGS. 8 and 9, an electrolytic plating solution 101 is supplied from the light-emitting element 10 side to start electrolytic plating. Thus, a metal film is grown from the first electrode part 11 of the light-emitting element 10 and the first conductive part 31 of the intermediate structure 30 as starting points, and a metal film is grown from the second electrode part 12 of the light-emitting element 10 and the second conductive part 32 of the intermediate structure 30 as starting points. When the metal film grown from the first conductive part 31 and the metal film grown from the first electrode part 11 are sufficiently integrated with each other and the metal film grown from the second conductive part 32 and the metal film grown from the second electrode part 12 are sufficiently integrated with each other, the electrolytic plating is terminated.

As a result, as illustrated in FIGS. 10 and 11, the first bonding part 41 and the second bonding part 42 are formed between the wiring substrate 35 and the light-emitting element 10. The first bonding part 41 is in contact with the entire lower surface of the first electrode part 11 of the light-emitting element 10 and a portion not covered with the holding part 33 in the first conductive part 31 of the intermediate structure 30. The second bonding part 42 is in contact with the entire lower surface of the second electrode part 12 of the light-emitting element 10 and a portion not covered with the holding part 33 in the second conductive part 32 of the intermediate structure 30.

The first bonding part 41 and the second bonding part 42 are partitioned from each other by the holding part 33 and the insulating part 13. Thus, the first bonding part 41 and the second bonding part 42 are insulated from each other. The first bonding part 41 and the second bonding part 42 may be or may not be in contact with the holding part 33 and the insulating part 13. When the first bonding part 41 or the second bonding part 42 is in contact with the holding part 33 and the insulating part 13, a step 44 may be formed at a position corresponding to a boundary between the holding part 33 and the insulating part 13 on lateral surfaces 43 extending in the third direction D3 in the first bonding part 41 or the second bonding part 42.

### Step of Removing Holding Part

Subsequently, the holding part 33 is removed.

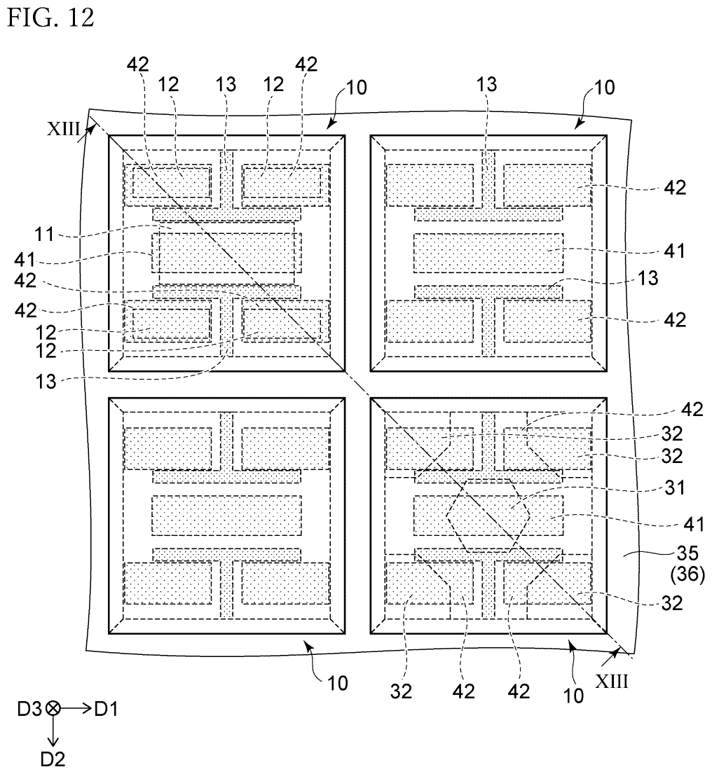

FIG. 12 is a schematic top view illustrating a step of removing the holding part.

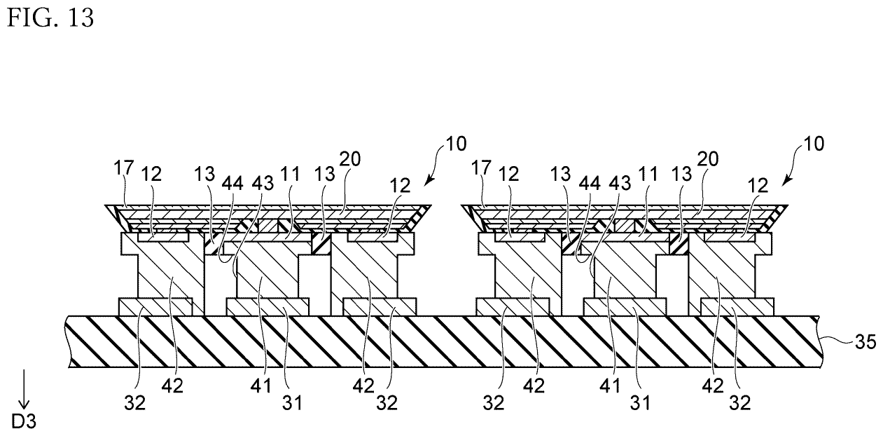

FIG. 13 is a schematic end view taken along line XIII-XIII illustrated in FIG. 12.

As illustrated in FIGS. 12 and 13, for example, a chemical liquid is brought into contact with the holding part 33 through a gap between the light-emitting elements 10. Thus, the holding part 33 is dissolved and removed. At this time, the insulating part 13 is not removed.

### Step of Forming Light Shielding Part

Subsequently, a light shielding part 50 is formed.

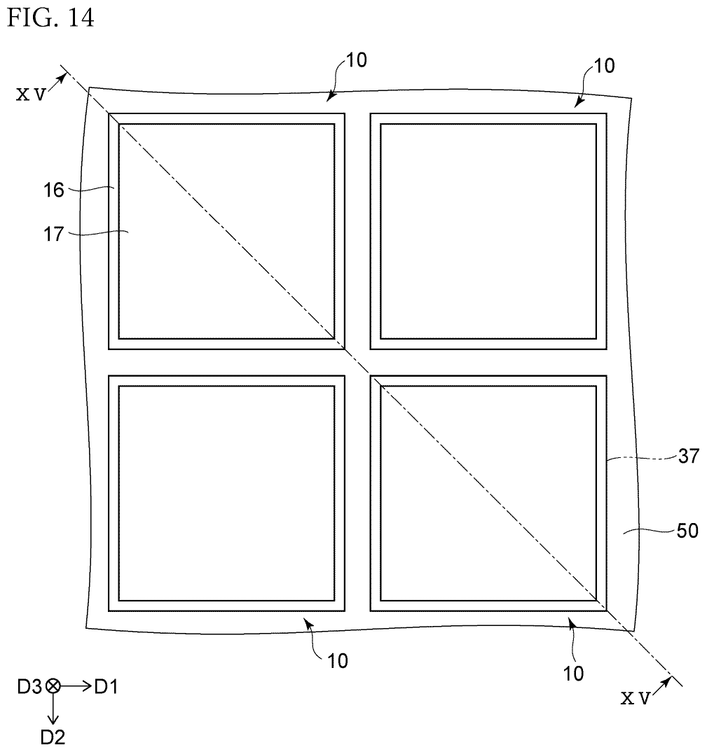

FIG. 14 is a schematic top view illustrating a step of forming the light shielding part.

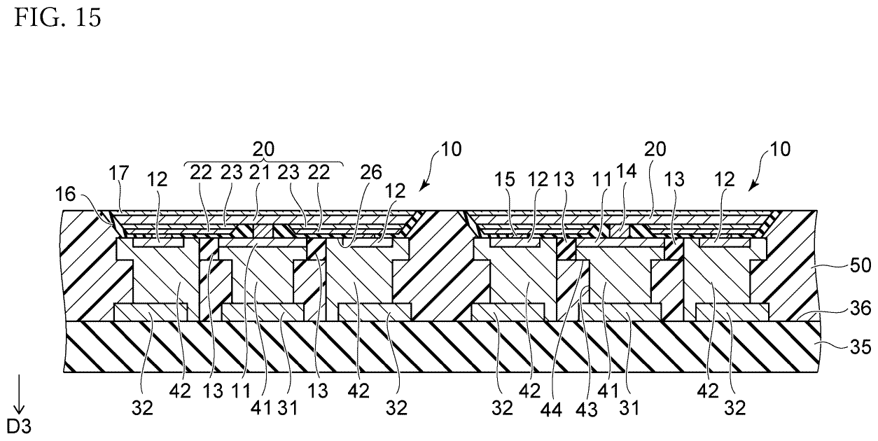

FIG. 15 is a schematic end view taken along line XV-XV illustrated in FIG. 14.

As illustrated in FIGS. 14 and 15, a light shielding material, for example, a paste-like resin material containing a light reflective material is poured between the wiring substrate 35 and the light-emitting elements 10 through the gap between the light-emitting elements 10. Subsequently, the resin material is heated and solidified. Subsequently, a portion of the solidified resin material disposed on the upper surface of the light-emitting element 10 is removed.

Thus, the light shielding part 50 is formed between the wiring substrate 35 and the light-emitting element 10. The light shielding part 50 covers the second surface 36 of the wiring substrate 35, lateral surfaces of the first bonding part 41, lateral surfaces of the second bonding part 42, and a lower surface and lateral surfaces of the light-emitting element 10, but does not cover an upper surface of the light-emitting element 10. The upper portions of the lateral surfaces of the light-emitting element 10 need not be covered with the light shielding part 50.

The lower surface of the light-emitting element 10 includes a lower surface of a portion of the insulating film 16 that covers the first surface 26 of the semiconductor layered body 20, a lower surface and lateral surfaces of the first electrode part 11, a lower surface and lateral surfaces of the second electrode part 12, and a lower surface and lateral surfaces of the insulating part 13. The lateral surfaces of the light-emitting element 10 include lateral surfaces of a portion of the insulating film 16 that covers the lateral surfaces 28 of the semiconductor layered body 20. The upper surface of the light-emitting element 10 includes the upper surface of the light-transmissive member 17. In this manner, the light-emitting module 1 according to the present embodiment is manufactured.

### Light-Emitting Module

The configuration of the light-emitting module 1 according to the present embodiment will be schematically described below.

The light-emitting module 1 according to the present embodiment includes the light-emitting element 10, the wiring substrate 35 including the second surface 36, the first conductive part 31 disposed on the second surface 36, the plurality of second conductive parts 32 disposed on the second surface 36 to be separated from the first conductive part 31, the first bonding part 41, and the second bonding part 42. The light-emitting element 10 includes the semiconductor layered body 20 including the first surface 26, the first electrode part 11 disposed on the first surface 26, the plurality of second electrode parts 12 disposed on the first surface 26 to be separated from the first electrode part 11, and the insulating parts 13. The insulating part 13 is disposed in areas between the first electrode part 11 and the plurality of second electrode parts 12 and at least one of areas between adjacent ones of the plurality of second electrode parts 12 on the first surface 26, and protrudes further away from the first surface 26 than the first electrode part 11 and the plurality of second electrode parts 12 protrude. The first bonding part 41 is in contact with the first conductive part 31 and an entirety of a surface of the first electrode part 11 facing the second surface 36. The second bonding part 42 is in contact with the second conductive part 32 and an entirety of a surface of the second electrode part 12 facing the second surface 36.

Details of the light-emitting module 1 according to the present embodiment will be described below.

As illustrated in FIGS. 14 and 15, the light-emitting module 1 includes the wiring substrate 35, the first conductive part 31, the second conductive part 32, the first bonding part 41, the second bonding part 42, and the light-emitting element 10. For example, the plurality of light-emitting elements 10 are disposed on the wiring substrate 35. The light-emitting elements 10 arrayed in a matrix along the first direction D1 and the second direction D2. Alternatively, the light-emitting module 1 may include the light shielding part 50.

The wiring substrate 35 is, for example, an ASIC substrate, and an integrated circuit (not illustrated) is provided inside the wiring substrate 35. The first conductive part 31 and the second conductive part 32 are disposed on the second surface 36, which is the upper surface of the wiring substrate 35, to be separated from each other. In the present embodiment, one first conductive part 31 and four second conductive parts 32 are disposed in each region 37 located at a region immediately below the light-emitting element 10. The first conductive part 31 is located at the center of the region 37, and the four second conductive parts 32 are each located at a corresponding one of the four corners of the region 37. The first conductive part 31 and the second conductive parts 32 are each connected to wiring lines (not illustrated) of the wiring substrate 35.

The first bonding part 41 made of a metal is disposed on the first conductive part 31. The first bonding part 41 is in contact with at least a portion of the upper surface of the first conductive part 31. Similarly, the second bonding part 42 made of a metal is disposed on the second conductive part 32. The second bonding part 42 is in contact with at least a portion of the upper surface of the second conductive part 32. The plurality of first bonding parts 41 and the plurality of second bonding parts 42 are separated from one another. At least one of the first bonding part 41 or the second bonding part 42 includes the step 44 on the lateral surface 43 extending in the third direction D3.

The first bonding part 41 is in contact with the entire lower surface of the first electrode part 11 of the light-emitting element 10.

The lower surface of the first electrode part 11 is a surface facing the second surface 36 of the wiring substrate 35. The first bonding part 41 may be in contact with the lateral surface of the first electrode part 11. The first bonding part 41 connects the first conductive part 31 to the first electrode part 11. Similarly, the second bonding part 42 is in contact with the entire lower surface of the second electrode part 12 of the light-emitting element 10. The lower surface of the second electrode part 12 faces the second surface 36 of the wiring substrate 35. The second bonding part 42 may be in contact with the lateral surface of the second electrode part 12. The second bonding part 42 connects the second conductive part 32 to the second electrode part 12.

In the third direction D3 from the first surface 26 toward the second surface 36, the protrusion length h of the insulating part 13 with respect to the first electrode part 11 is preferably in a range of 0.5 μm to 2.0 μm. The insulating part 13 may be or may not be in contact with the first bonding part 41 and the second bonding part 42. The other configurations of the light-emitting element 10 are as described above.

The light shielding part 50 is disposed between the wiring substrate 35 and the light-emitting element 10 and between the light-emitting elements 10. The light shielding part 50 is made of an opaque insulating material, for example, a resin material containing a light reflective material. The light shielding part 50 covers the second surface 36 of the wiring substrate 35, a region of the first conductive part 31 not in contact with the first bonding part 41, a region of the second conductive part 32 not in contact with the second bonding part 42, regions of the lateral surfaces of the first bonding part 41 not in contact with the insulating part 13, regions of the lateral surfaces of the second bonding part 42 not in contact with the insulating part 13, a region of the lower surface of the light-emitting element 10 not in contact with the first bonding part 41 and the second bonding part 42, and a lower portion or the entirety of the lateral surface of the light-emitting element 10. The light shielding part 50 covers none of the lower surface of the first electrode part 11, the lower surface of the second electrode part 12, and the upper surface of the light-emitting element 10.

### Effects

Subsequently, an effect of the present embodiment will be described.

In the present embodiment, in the step of providing the light-emitting element 10 illustrated in FIGS. 1 and 2, the light-emitting element 10 is provided with the insulating part 13 protruding further in the third direction D3 than the first and second electrode parts 11 and 12 protrude. Thus, in the step of disposing the light-emitting element 10 on the intermediate structure 30 illustrated in FIGS. 6 and 7, the insulating part 13 is brought into contact with the holding part 33.

Thus, even when the position of the light-emitting element 10 is shifted with respect to the wiring substrate 35, the first electrode part 11 and the second electrode part 12 are avoided from coming into contact with the holding part 33. As a result, in the step of forming the first bonding part 41 and the second bonding part 42 illustrated in FIGS. 8 to 11, a contact area between the first electrode part 11 and the first bonding part 41 and a contact area between the second electrode part 12 and the second bonding part 42 are less likely to be reduced.

Thus, the bonding strength between the wiring substrate 35 and the light-emitting element 10 is less likely to decrease. Further, conductivity between the first electrode part 11 and the first conductive part 31 and conductivity between the second electrode part 12 and the second conductive part 32 are less likely to decrease.

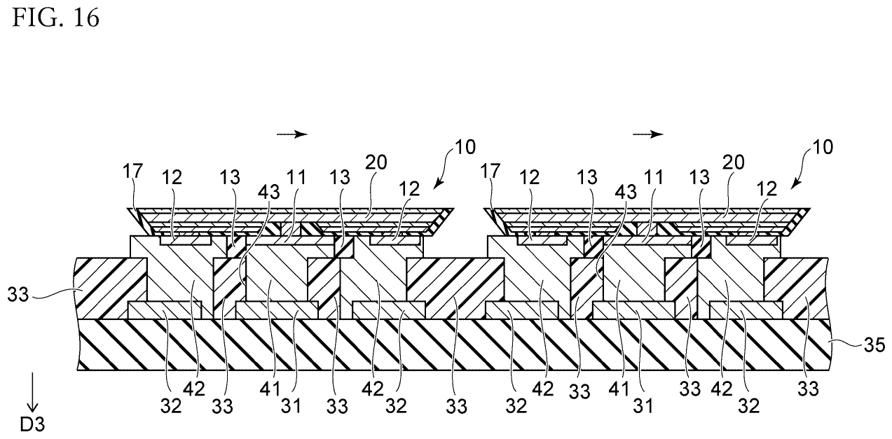

FIG. 16 is a schematic end view illustrating effects of the present embodiment.

FIG. 16 illustrates a case in which the position of the light-emitting element 10 is shifted with respect to the wiring substrate 35 in the step illustrated in FIG. 11. Even in the case in which the position of the light-emitting element 10 is shifted, the holding part 33 does not come into contact with either the first electrode part 11 or the second electrode part 12, the first bonding part 41 comes into contact with the entire lower surface of the first electrode part 11, and the second bonding part 42 comes into contact with the entire lower surface of the second electrode part 12. As described above, according to the present embodiment, there can be provided the light-emitting module 1 in which the bonding strength between the wiring substrate 35 and the light-emitting element 10 is less likely to decrease even when the position of the light-emitting element 10 is shifted with respect to the wiring substrate 35.

In the light-emitting module 1 according to the present embodiment, the plurality of active layer parts 23 and the plurality of second semiconductor layer parts 22 are provided for one first semiconductor layer 21 in the light-emitting element 10. Each of the plurality of second semiconductor layer parts 22 is connected to a corresponding one of the plurality of second electrode parts 12. Thus, the light-emitting element 10 is divided into a plurality of light-emitting regions, which can be controlled independently of each other. As a result, in the light-emitting module 1, the definition of pixels can be increased.

Further, in the present embodiment, in each light-emitting element 10, four second electrode parts 12 are provided and arrayed along the first direction D1 and the second direction D2. The insulating part 13 is provided with the first portion 13a extending in the second direction D2 and the second portion 13b extending in the first direction D1, the holding part 33 is provided with the first branch portion 33a extending in the second direction D2 and the second branch portion 33b extending in the first direction D1, and in the step of disposing the light-emitting element 10 on the intermediate structure 30, the first portion 13a is brought into contact with the first branch portion 33a, and the second portion 13b is brought into contact with the second branch portion 33b. Thus, because the light-emitting element 10 is supported by the second branch portion 33b and the second portion 13b each extending in the first direction D1 and the first branch portion 33a and the first portion 13a each extending in the second direction D2, the position of the light-emitting element 10 is stabilized.

Further, the insulating part 13 is not disposed between the first electrode part 11 and end edges of the light-emitting element 10 on both sides in the first direction D1. Further, the insulating part 13 is not disposed between the second electrode part 12 and the end edge of the light-emitting element 10 on one side in the first direction D1. This makes it easier for the electrolytic plating solution 101 to reach the first electrode part 11, the second electrode part 12, the first conductive part 31, and the second conductive part 32 in the steps illustrated in FIGS. 8 and 9.

Furthermore, in the present embodiment, as illustrated in FIG. 2, the protrusion length h of the insulating part 13 in the third direction D3 with respect to the first electrode part 11 is set in a range from 0.5 μm to 2.0 μm. By setting the protrusion length h to 0.5 μm or more, even when the holding part 33 is crushed and the distal end portion of the insulating part 13 enters the holding part 33 when the insulating part 13 is brought into contact with the holding part 33, a gap between the first electrode part 11 and the holding part 33 can be secured and the holding part 33 can be suppressed from coming into contact with the first electrode part 11.

Similarly, the holding part 33 can also be suppressed from coming into contact with the second electrode part 12. Thus, the first electrode part 11 and the second electrode part 12 can be suppressed from being covered with the holding part 33, and the first bonding part 41 and the second bonding part 42 can be provided in contact with the entire lower surfaces of the first electrode part 11 and the second electrode part 12, respectively.

Furthermore, in the present embodiment, as illustrated in FIG. 7, in the step of disposing the light-emitting elements 10 on the intermediate structure 30, the width W1 of the insulating part 13 is smaller than the width W2 of the holding part 33 in one cross section. Thus, even when the position at which the light-emitting element 10 is disposed is shifted with respect to the wiring substrate 35, the insulating part 13 can be easily brought into contact with the holding part 33. In other words, the tolerance for the positional shift of the light-emitting element 10 is improved.

Furthermore, in the present embodiment, as illustrated in FIGS. 14 and 15, the light shielding part 50 is provided between the wiring substrate 35 and the light-emitting element 10. The light shielding part can increase the bonding strength between the wiring substrate 35 and the light-emitting element 10. Further, the light shielding part can reduce diffuse reflection of light emitted from any light-emitting element 10 between the wiring substrate 35 and another light-emitting element 10. As a result, in the light-emitting module 1, a contrast between the light-emitting element 10 that is turned on and the light-emitting element 10 that is turned off is improved, and a resolution of a light emission pattern is improved.

Furthermore, in the present embodiment, at least one selected from the group consisting of the plurality of first bonding parts 41 and the plurality of second bonding parts 42 includes the step 44 on the lateral surface 43 extending in the third direction D3. As a result, the adhesion between the light shielding part 50 and the first bonding part 41 or the second bonding part 42 in which the step 44 is formed is improved by an anchor effect. Thus, the bonding strength between the wiring substrate 35 and the light-emitting element 10 is improved.

Furthermore, in the present embodiment, the first bonding part 41 and the second bonding part 42 are formed by electrolytic plating.

Thus, the first bonding part 41 and the second bonding part 42 can be efficiently formed.

### Comparative Example

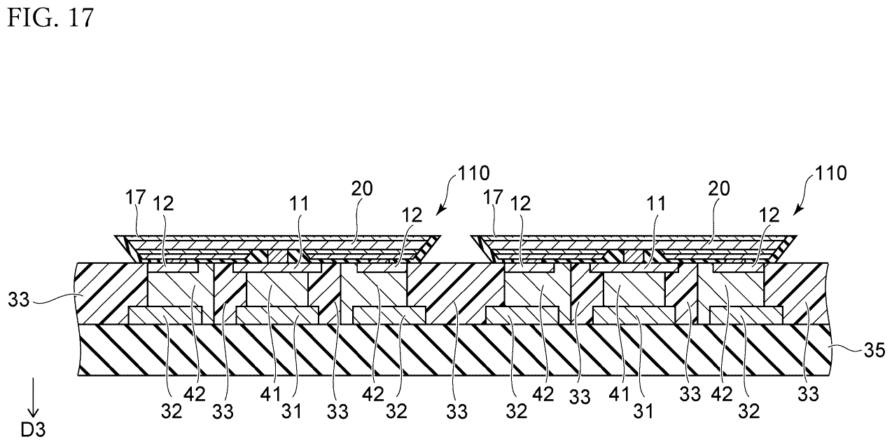

FIG. 17 is a schematic end view illustrating a method for manufacturing a light-emitting module according to the present comparative example, and illustrates a case in which a positional shift of a light-emitting element is small with respect to a wiring substrate.

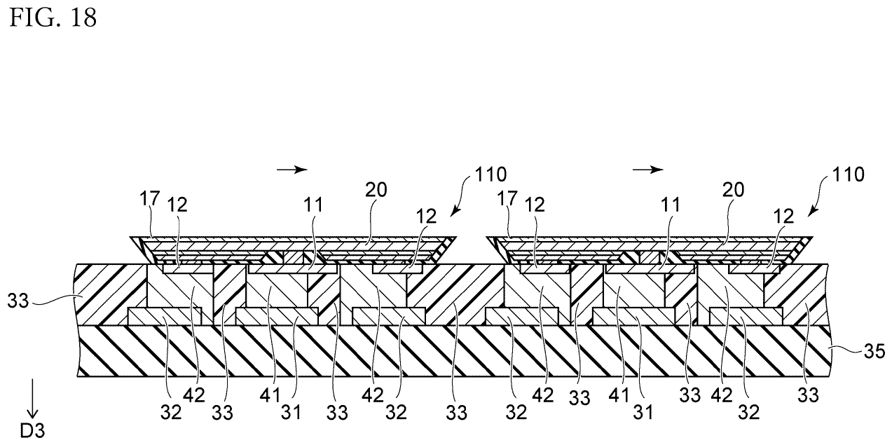

FIG. 18 is a schematic end view illustrating the method for manufacturing the light-emitting module according to the present comparative example, and illustrates a case in which the positional shift of the light-emitting element is large with respect to the wiring substrate.

As illustrated in FIG. 17, in the present comparative example, the insulating part 13 is not provided in a light-emitting element 110.

In the present comparative example, when the light-emitting element 110 is disposed on the wiring substrate 35, the holding part 33 may come into contact with a portion of the lower surface of the first electrode part 11 and a portion of the lower surface of the second electrode part 12. In this case, because the first bonding part 41 and the second bonding part 42 are not in contact with regions coming into contact with the holding part 33 on the lower surface of the first electrode part 11 and the lower surface of the second electrode part 12, respectively, the bonding strength between the wiring substrate 35 and the light-emitting element 110 may decrease.

As illustrated in FIG. 18, when the positional shift of the light-emitting element 110 is large with respect to the wiring substrate 35, the above-described tendency becomes more remarkable. As described above, in the present comparative example, because the insulating part 13 is not provided, when the position of the light-emitting element 110 is shifted with respect to the wiring substrate 35, the bonding strength between the wiring substrate 35 and the light-emitting element 110 is likely to decrease.

The above-described embodiments have been presented by way of example embodying the present invention, and are not intended to limit the scope of the present invention. For example, the addition, deletion or modification of several components or steps in the above-described embodiment are also included in the present invention.

The present invention can be utilized for a light source for a headlight of a vehicle and the like.

What is claimed is:

1. A method for manufacturing a light-emitting module, the method comprising:
providing a light-emitting element comprising:
a semiconductor layered body including a first surface,
a first electrode part disposed on the first surface,
a plurality of second electrode parts disposed on the first surface and separated from the first electrode part, and
an insulating part disposed in areas between the first electrode part and the plurality of second electrode parts and in at least one of areas between adjacent ones of the plurality of second electrode parts on the first surface, the insulating part protruding further away from the first surface than the first electrode part and the plurality of second electrode parts protrude;
providing an intermediate structure comprising:
a wiring substrate including a second surface,
a first conductive part disposed on the second surface,
a plurality of second conductive parts disposed on the second surface and separated from the first conductive part, and
a holding part disposed in areas between the first conductive part and the plurality of second conductive parts and in at least one of areas between adjacent ones of the plurality of second conductive parts on the second surface;
disposing the light-emitting element on the intermediate structure by bringing the insulating part into contact with the holding part; and
forming a first bonding part and a second bonding part, the first bonding part being in contact with the first electrode part and the first conductive part, and the second bonding part being in contact with the second electrode part and the second conductive part.

2. The method for manufacturing a light-emitting module according to claim 1, wherein:
the semiconductor layered body comprises:
a first semiconductor layer of a first conductivity type,
a plurality of active layer parts, and
a plurality of second semiconductor layer parts of a second conductivity type;
the first semiconductor layer, a first of the plurality of active layer parts, and a first respective one of the plurality of second semiconductor layer parts are arranged in this order;
the first electrode part is electrically connected to the first semiconductor layer; and
each of the plurality of second electrode parts is electrically connected to a respective one of the plurality of second semiconductor layer parts.

3. The method for manufacturing a light-emitting module according to claim 1, wherein:
the plurality of second electrode parts comprises four second electrode parts arrayed along a first direction and a second direction intersecting the first direction.

4. The method for manufacturing a light-emitting module according to claim 3, wherein:
the insulating part comprises:
a first portion extending in the second direction, and
a second portion extending in the first direction;
the holding part comprises:
a first branch portion extending in the second direction, and
a second branch portion extending in the first direction; and
in the disposing of the light-emitting element on the intermediate structure, the first portion is brought into contact with the first branch portion, and the second portion is brought into contact with the second branch portion.

5. The method for manufacturing a light-emitting module according to claim 3, wherein:
the insulating part is not disposed between the first electrode part and end edges of the light-emitting element on both sides of the light-emitting element in the first direction, and is not disposed between the second electrode part and the end edge of the light-emitting element on one side of the light-emitting element in the first direction.

6. The method for manufacturing a light-emitting module according to claim 1, wherein:
a protrusion length of the insulating part with respect to the first electrode part in a third direction from the first surface toward the second surface is in a range of 0.5 μm to 2.0 μm.

7. The method for manufacturing a light-emitting module according to claim 1, wherein:
in the disposing of the light-emitting element on the intermediate structure, a width of the insulating part in a cross section is smaller than a width of the holding part in the cross section.

8. The method for manufacturing a light-emitting module according to claim 1, wherein:
the light-emitting element comprises:
a lower surface including the first surface,
an upper surface disposed on a side opposite to the lower surface, and
a lateral surface disposed between the lower surface and the upper surface; and
the method further comprises:
after the forming of the first bonding part and the second bonding part, removing the holding part; and
after the removing of the holding part, forming a light shielding part to cover the lower surface and the lateral surface of the light-emitting element.

9. The method for manufacturing a light-emitting module according to claim 1, wherein:
the first bonding part and the second bonding part are formed by electrolytic plating.

10. A light-emitting module comprising:
a light-emitting element comprising:
a semiconductor layered body including a first surface,
a first electrode part disposed on the first surface,
a plurality of second electrode parts disposed on the first surface and separated from the first electrode part, and
an insulating part disposed in areas between the first electrode part and the plurality of second electrode parts and in at least one of areas between adjacent ones of the plurality of second electrode parts on the first surface, the insulating part protruding further away from the first surface than the first electrode part and the plurality of second electrode parts protrude;
a wiring substrate including a second surface;
a first conductive part disposed on the second surface;
a plurality of second conductive parts disposed on the second surface and separated from the first conductive part;
a first bonding part in contact with the first conductive part and an entirety of a surface of the first electrode part facing the second surface; and
a second bonding part in contact with the second conductive part and an entirety of a surface of the second electrode part facing the second surface.

11. The light-emitting module according to claim 10, wherein:
the semiconductor layered body of the light-emitting element comprises:
a first semiconductor layer of a first conductivity type,
a plurality of active layer parts, and
a plurality of second semiconductor layer parts of a second conductivity type;
the first semiconductor layer, a first of the plurality of active layer parts, and a first respective one of the plurality of second semiconductor layer parts are arranged in this order;
the first electrode part is electrically connected to the first semiconductor layer; and
each of the plurality of second electrode parts is electrically connected to a corresponding one of the plurality of second semiconductor layer parts.

12. The light-emitting module according to claim 10, wherein:
the plurality of second electrode parts comprises four second electrode parts arrayed along a first direction and a second direction intersecting the first direction.

13. The light-emitting module according to claim 10, wherein:
at least one of the first bonding part or the second bonding part comprises a step on a lateral surface extending in a third direction from the first surface toward the second surface.

14. The light-emitting module according to claim 10, wherein:
a protrusion length of the insulating part with respect to the first electrode part in a third direction from the first surface toward the second surface is in a range of 0.5 μm to 2.0 μm.

15. The light-emitting module according to claim 10, wherein:
the light-emitting element comprises:
a lower surface including the first surface,
an upper surface disposed on a side opposite to the lower surface, and
a lateral surface located between the lower surface and the upper surface; and
the module further comprises a light shielding part covering the lower surface and the lateral surface of the light-emitting element.
